(19) United States
(12) Patent Application Publication
(10) Pub. No.: US 2012/0098129 A1
(43) Pub. Date: Apr. 26, 2012

(54) METHOD OF MAKING A MULTI-CHIP MODULE HAVING A REDUCED THICKNESS AND RELATED DEVICES

(75) Inventors: Thomas Reed, West Melbourne, FL (US); David Herndon, Palm Bay, FL (US); David Nicol, West Melbourne, FL (US); Michael Weatherspoon, West Melbourne, FL (US)

(73) Assignee: Harris Corporation, Melbourne, FL (US)

(21) Appl. No.: 12/910,131

(22) Filed: Oct. 22, 2010

(51) Int. Cl. H01L 23/48; H01L 23/52; H01L 21/50

(52) U.S. Cl. 257/738; 438/108; 257/778; 257/E21.499; 257/E23.021; 257/E23.141

(57) ABSTRACT

A method of making a multi-chip module may include forming an interconnect layer stack on a sacrificial substrate. The interconnect layer stack may include patterned electrical conductor layers and a dielectric layer between adjacent patterned electrical conductor layers. The method may further include electrically coupling a first integrated circuit (IC) die in a flip chip arrangement to an uppermost patterned electrical conductor layer, and forming a first underfill dielectric layer between the first IC die and adjacent portions of the interconnect layer stack. The method further may include removing the sacrificial substrate to expose a lowermost patterned electrical conductor layer, and electrically coupling at a second integrated circuit die in a flip chip arrangement to the lowermost patterned electrical conductor layer. Still further, the method may include forming a second underfill dielectric layer between the second IC die and adjacent portions of the interconnect layer stack.

### FIELD OF THE INVENTION

The present invention relates to the field of electronics, and, more particularly, to multi-chip modules, and related methods.

### BACKGROUND OF THE INVENTION

The growing desire for reduced size electronic chip packages is creating a demand for relatively thin, light weight, and high density substrates. Current state of the art substrate technology may not be readily capable of producing these relatively thin microelectronic circuits. Increasing demand for thinner and more discrete systems is being driven by the decreasing envelope size (form factor), reducing weight, and increasing circuit density of microelectronic packaging approaches. Reduction in minimum feature size at the chip level may be happening more quickly than at the board/substrate level, and because of this, traditional substrate materials may not be able to take advantage of reduced size integrated circuits (IC). Ultimate system miniaturization may be accomplished by flip chip attachment. It may be desirable to provide a substrate whose form factor is determined based upon chip size, as opposed to routing area (x, y dimensions) and layer thickness (z dimensions), as with traditional printed wiring board/substrate technology.

A printed wire board (PWB) substrate, for example, including a high density interconnect (HDI) may be relatively inexpensive, as fabrication processes of a PWB are typically stable in terms of technological advancement. However, using a PWB substrate may be limited in terms of routing density. For example, a PWB may allow about 25 microns of spacing between routing on a given layer. Thus, to accommodate the routing density, more routing layers may be desired, which may cause the PWB to be relatively thick. Moreover, there may be a relatively high coefficient of thermal expansion (CTE) between the PWB and the components mounted thereon.

A liquid crystal polymer (LOP) substrate is generally thinner than a traditional PWB, for example. An LCP substrate may also be relatively near hermetic. Using an LOP substrate, while having a relatively low cost, may generally cost more than using a PWB. Moreover, the ratio of the number of layers to thickness may not be desirable. For example, going from two layers to four layers increases the thickness of an LCP substrate by a factor of three. Additionally, an LCP substrate is limited to reduced temperature fabrication processes. For example, an LCP substrate may begin to breakdown at temperatures in excess of 300 degrees Celsius, which may limit methods of electronic circuit component attachment. For example, some electronic circuit component attachment processes may exceed temperatures of 350 degrees Celsius.

A silicon interposer may provide an increased ratio of the number of layers to thickness. For example, layers may be added with a reduced effect on overall thickness. Additionally, a silicon interposer has a relatively low CTE. However, using a silicon interposer is relatively expensive, and more expensive than using LCP or a PWB. Using a silicon interposer may result in an increased overall thickness, as the silicon interposer is part of the substrate, i.e. bulk, and not the layers. Moreover, a silicon interposer is relatively fragile, and thus may be thicker than 250 microns. Indeed, while thinner silicon interposers may be used, they are subject to increased breakage, as the silicon interposer is formed of a single crystal, it has a tendency to cleave along the crystal plane. The increased thickness may be problematic for applications where a relatively thin module is desired.

A polyimide substrate has an increased thermal budget. In other words, a polyimide substrate may withstand increased temperatures, as may occur during bonding of electronic circuit components. A polyimide substrate has an increased cost as compared to LCP and a PWB, but may be less expensive than using a silicon interposer, for example. Additionally, similar to LCP, the ratio of the number of layers to thickness may not be desirable.

U.S. Pat. No. 6,406,942 to Honda discloses a multi-layer wiring structure formed on a metal plate, which is etched away. An insulating substrate having through hole sections is bonded to multi-layer wiring structure, a conductive bonding agent is embedded into the through hole section, and a flip chip die is mounted to one side of the multi-layer structure. Solder balls are attached to the through hole sections.

### SUMMARY OF THE INVENTION

In view of the foregoing background, it is therefore an object of the present invention to reduce a thickness of a multi-chip module.

This and other objects, features, and advantages are provided by a method of making a multi-chip module. The method includes forming an interconnect layer stack on a sacrificial substrate. The interconnect layer stack includes a plurality of patterned electrical conductor layers and a dielectric layer between adjacent patterned electrical conductor layers, for example. The method may further include electrically coupling at least one first integrated circuit (IC) die in a flip chip arrangement to an uppermost patterned electrical conductor layer, and forming a first underfill dielectric layer between the at least one first IC die and adjacent portions of the interconnect layer stack. The method further includes removing the sacrificial substrate to expose a lowermost patterned electrical conductor layer, and electrically coupling at least one second integrated circuit die in a flip chip arrangement to the lowermost patterned electrical conductor layer. Still further, the method includes forming a second underfill dielectric layer between the at least one second IC die and adjacent portions of the interconnect layer stack, for example. Accordingly, the multi-chip module has a reduced thickness as compared to prior art multi-chip modules.

The sacrificial substrate may be glass, for example, and the dielectric layer may include polyimide, for example. The first and second underfill dielectric layers may each include an epoxy material.

The interconnect layer stack may be formed to have a thickness less than 50 microns, for example. The sacrificial substrate may be removed by chemical etching, or a combination of mechanical polishing and chemical etching.

Another aspect is directed to a method of making a multi-chip module wherein a plurality of solder contacts is on the lowermost patterned electrical conductor layer instead of another flip chip IC. Forming the plurality of solder contacts includes forming a ball-grid array.

A device aspect is directed to a multi-chip module including an interconnect layer stack. The interconnect layer stack includes a plurality of patterned electrical conductor layers and a dielectric layer between adjacent patterned electrical conductor layers. The multi-chip module further includes at least one first IC die in a flip chip arrangement electrically coupled to an uppermost patterned electrical conductor layer, and a first underfill dielectric layer between the at least one first IC die and adjacent portions of the interconnect layer stack, for example. The multi-chip module further includes at least one second IC die in a flip chip arrangement electrically coupled to a lowermost patterned electrical conductor layer, and a second underfill dielectric layer between the at least one second IC die and adjacent portions of the interconnect layer stack.

Another device aspect is directed to a multi-chip module that includes an interconnect layer stack. The interconnect layer stack includes a plurality of patterned electrical conductor layers and a dielectric layer between adjacent patterned electrical conductor layers. The interconnect layer stack may have a thickness less than 50 microns, for example. The multi-chip module further includes at least one IC die in a flip chip arrangement electrically coupled to an uppermost patterned electrical conductor layer, and a first underfill dielectric layer between the at least one IC die and adjacent portions of the uppermost patterned electrical conductor layer, for example. The multi-chip module further includes a plurality of solder contacts coupled to a lowermost patterned electrical conductor layer.

### BRIEF DESCRIPTION OF THE DRAWINGS

FIG. 1 is an enlarged cross-sectional view of a multi-chip module in accordance with the present invention.

FIG. 2 is a series of cross-sectional views illustrating a method of making the multi-chip module in FIG. 1.

FIG. 3 is an enlarged cross-sectional view of a multi-chip module in accordance with another embodiment of the present invention.

FIG. 4 is a series of cross-sectional views illustrating a method of making the multi-chip module in FIG. 3.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternate embodiments.

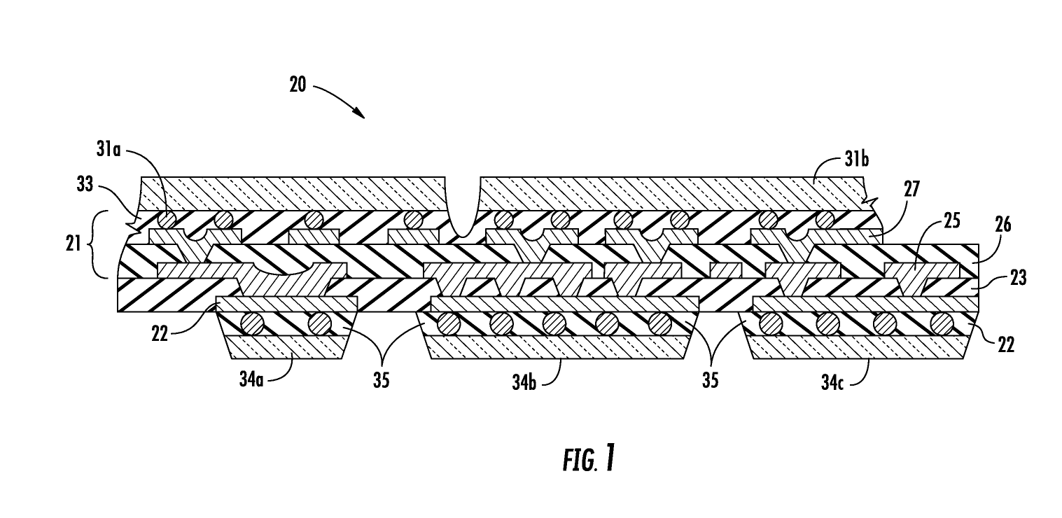

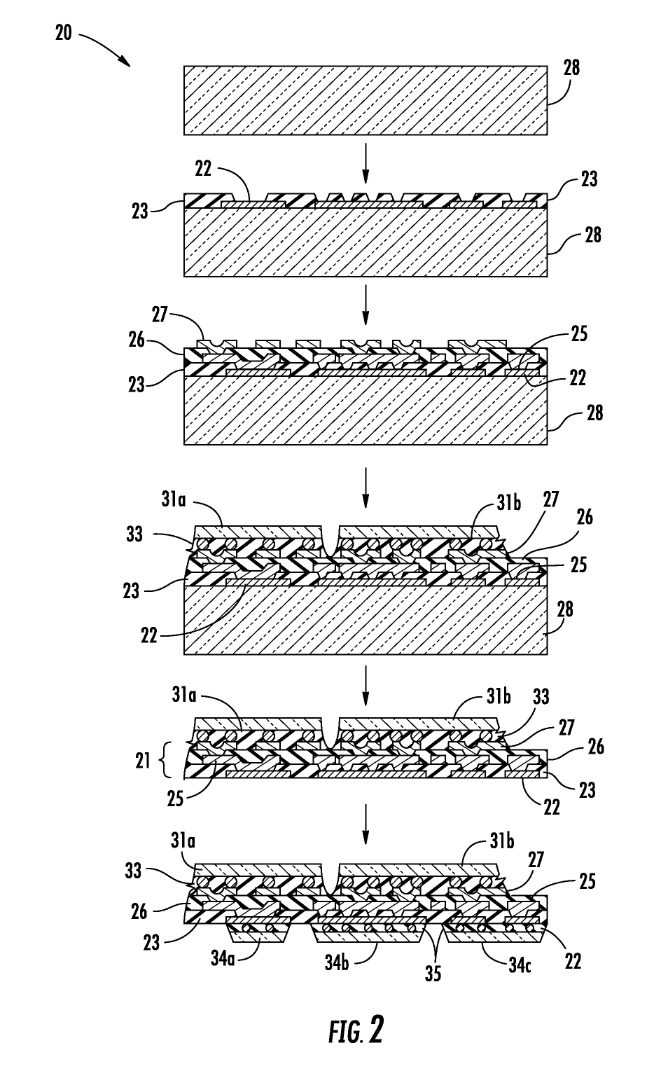

Referring initially to FIGS. 1 and 2, a method of making a multi-chip module 20 will be described. The method includes forming an interconnect layer stack 21 on a sacrificial substrate 28. The interconnect Layer stack 2 includes a first patterned electrical conductor layer 22, or pad layer, having spaces. The first patterned electrical conductor layer 22 is a thin-film metallic layer, for example, and may include copper.

The interconnect layer stack 21 also includes a first dielectric layer 23, and more particularly, polyimide, and fills the spaces in the first patterned electrical conductor layer 22. The first dielectric layer 23 also has spaces. As will be appreciated by those skilled in the art, polyimide provides increased structural integrity and, thus, contributes to increasing the overall strength of the multi-chip module 20. Materials other than polyimide may also be used, as will be appreciated by those skilled in the art

The interconnect layer stack 21 also includes a second patterned electrical conductor layer 25, or routing layer, that is formed on the first dielectric layer 23 and fills the spaces of the first dielectric layer. In other words, the first dielectric layer 23 is between the first and second patterned electrical conductor layers 22, 25. The second patterned electrical conductor layer 25 also has spaces. A second dielectric layer 26, also polyimide, for example, is formed on the second patterned electrical conductor layer 25 and fills the spaces thereof.

The interconnect layer stack 21 further includes a third patterned electrical conductor layer 27, or second pad layer, formed on second dielectric layer 26 and filling the spaces thereof. The third patterned electrical conductor layer 27 also has spaces.

The interconnect layer stack 21, i.e. the first, second, and third patterned electrical conductor layers 22, 25, 27, and the first and second dielectric layers 23, 26 would typically have a combined thickness of less than 50 microns. More particularly, the interconnect layer stack 21 may have a combined thickness in the range of 5 to 50 microns, and more preferably, 10 to 25 microns.

As will be appreciated by those skilled in the art, the build-up of patterned electrical conductor layers with dielectric layers between adjacent patterned electrical conductor layers may continue until a desired number of layers have been formed on the sacrificial substrate 28. In other words, any number of layers may be stacked to a desired thickness. However, the preferred combined thickness of the interconnect layer stack 21 (excluding the glass substrate 28) may be less than 50 microns to form a compact module.

A pair of first integrated circuit (IC) die 31a, 31b in a flip chip arrangement is electrically coupled to an uppermost patterned electrical conductor layer, i.e. the third patterned electrical conductor layer 27. While a pair of IC die 31a, 31b are illustrated, any number of IC die may be electrically coupled to the uppermost patterned electrical conductor layer. Additionally, other components, for example, surface mount technology (SMT) components, or a combination of components, may be electrically coupled to the uppermost patterned electrical conductor layer.

A first underfill dielectric layer 33 is formed between the pair of first IC die 31a, 31b and adjacent portions of the interconnect layer stack 21. The first underfill dielectric layer 33 is an epoxy material, for example, Loctite™ 3568™, and provides increased structural rigidity to, or strengthens, the multi-chip module 20. The first underfill dielectric layer 33 may also mechanically couple the multi-chip module 20, and in particular, the pair of first IC die 31a, 31b to the adjacent portions of the uppermost patterned electrical conductor layer 27. Other types of underfill materials may be used, which may have an increased resistance to a chemical etching solution, as will be appreciated by those skilled in the art.

The sacrificial substrate 28 may be a glass substrate, for example. As will be appreciated by those skilled in the art, the glass sacrificial substrate advantageously provides dimensional stability to enable the fabrication of ultra-high density interconnects (UHDI), for example, with 10 microns lines and spaces to connect high density input-output (I/O) components. Of course, the sacrificial substrate may be another material.

The glass sacrificial substrate 28 is removed to expose a lowermost patterned electrical conductor layer 22. The first dielectric layer 23 is also exposed by the removal of the sacrificial substrate 28. The sacrificial substrate 28 is removed by etching. More particularly, the sacrificial substrate 28 is etched using hydrofluoric acid (HF), for example. Other etching techniques may also be used, for example, a combination of mechanical polishing and chemical etching. The HF etching solution advantageously reacts to remove the glass substrate 28, but has a reduced reaction with the copper circuitry 22 and/or the first (polyimide) dielectric layer 23, i.e. the patterned interconnect layer stack 21.

Three second integrated circuit die in a flip chip arrangement 34a, 34b, 34c are electrically coupled to the lowermost patterned electrical conductor layer 22. While three second IC die 34a, 34b, 34c are illustrated, any number of second IC die may be electrically coupled to the lowermost patterned electrical conductor layer 22. Additionally, other components, for example, SMT components, or a combination of components, may be electrically coupled to the lowermost interconnect layer 22.

A second underfill dielectric layer 35 is formed, between the second IC die 34a, 34b, 34c and adjacent portions of the lowermost patterned electrical conductor layer 22 and the first dielectric layer 23. The second underfill layer 35 is an epoxy material, for example, Loctite™ 3568™, and provides increased structural rigidity to, or strengthens, the multi-chip module 20. The second underfill dielectric layer 35 may also mechanically couple the multi-chip module 20, and in particular, the second IC die 34a, 34b, 34c to the adjacent portions of the lowermost patterned electrical conductor layer 22.

Moreover, bond pads (not shown) may be coupled to selected ones of the patterned electrical conductor layers to couple to the other components, for example, components external to the multi-chip module.

Additionally, the SMT components, IC die, or combination thereof may be encapsulated with a potting material (not shown). The potting material may increase the mechanical stability of the module.

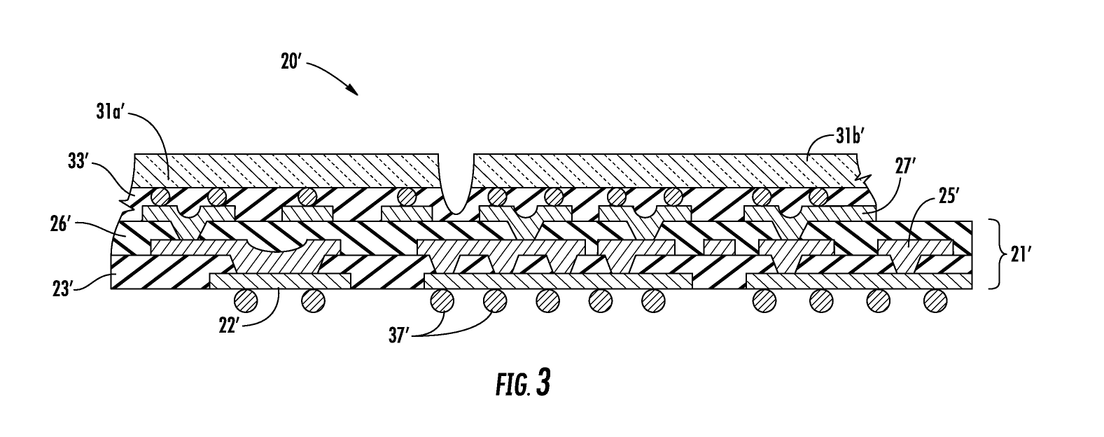

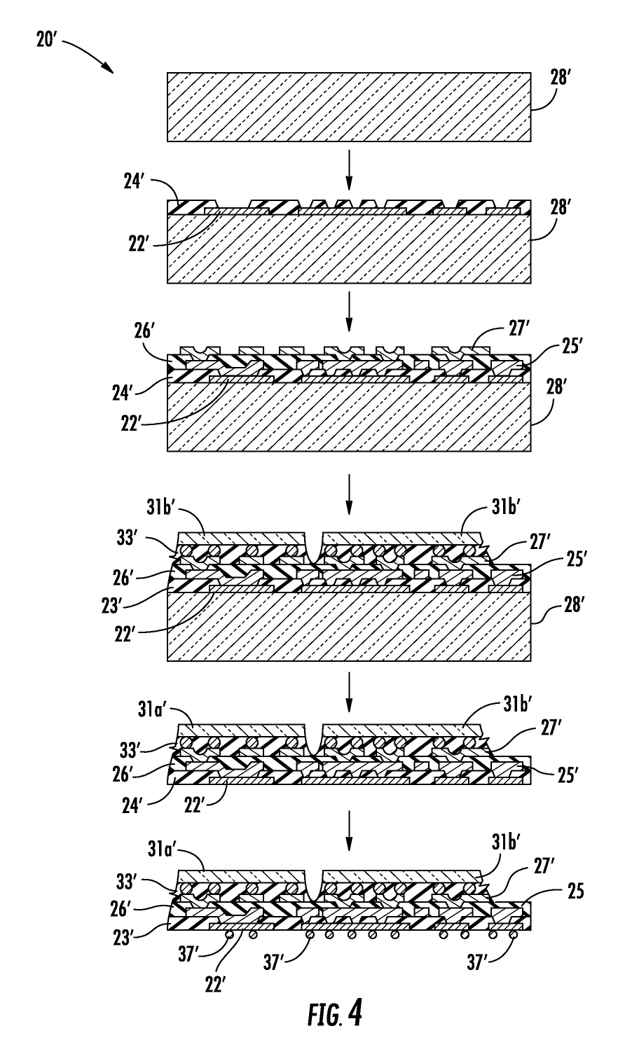

Referring now to FIGS. 3 and 4, another embodiment of a method of making a multi-chip module 20′ is described. Similar to the method described above with the interconnect layer stack formed on the sacrificial substrate 28′, a pair of first IC die 31a′, 31b′ in flip chip arrangement is electrically coupled to the uppermost patterned electrical conductor layer 27′, and the sacrificial substrate is removed to expose the lowermost patterned electrical conductor layer 22′ and first dielectric layer 23′. Solder contacts 37′ are formed on the lowermost patterned electrical conductor layer 22′. More particularly, the solder contacts 37′ are a solder ball attachment, or ball-grid array. Other types of solder contacts 37′ may be formed on the lowermost interconnect layer 22′, for example, a land grid array. As will be appreciated by those skilled in the art, in the present embodiment, there are no second integrated circuit die in a flip chip arrangement electrically coupled to the lowermost patterned electrical conductor layer 22′, and thus there is not a second dielectric underfill layer. This may advantageously allow the multi-chip module 20′ to couple to or be integrated with other system components. Of course, the solder contact 37′ may be used in conjunction with the IC die in a flip chip configuration, as described above, or in conjunction with other components.

Advantageously, the method of making the multi-chip module allows the formation of a relatively thin, and increasingly relatively dense multi-chip module. Advantageously, components, such as IC die, for example, may be placed on both sides of the interconnect layer stack, or alternatively, allow the multi-chip module to be soldered using a ball-grid array footprint, for example. Indeed, a multi-chip module made using the above method creates a reduced size form factor multi-chip module, as the size may be mostly dependent on the chip and die sizes used on the interconnect layer stack. Still further, the method may reduce the design cycle costs. Indeed, the method may be performed in a reduced time as compared to typical long lead time processes used for current three-dimension (3D) integration.

A device aspect is directed to a multi-chip module 20 including an interconnect layer stack 21. The interconnect layer stack 21 includes a plurality of patterned electrical conductor layers 22, 25, 27 and a dielectric layer 23, 26 between, adjacent patterned electrical conductor layers. The multi-chip module 20 further includes a pair of first IC die 31a, 31b in a flip chip arrangement electrically coupled to an uppermost patterned electrical conductor layer 27, and a first underfill dielectric layer 33 between the pair of first IC die 31a, 31b and adjacent portions of the interconnect layer stack. Any number of first IC die may be electrically coupled to the uppermost patterned electrical conductor layer 27. The multi-chip module 20 further includes three second IC die 34a, 34b, 340 in a flip chip arrangement electrically coupled to a lowermost patterned electrical conductor layer 22, and a second underfill dielectric layer 35 between the three second IC die and adjacent portions of the interconnect layer stack 21. Any number of second IC die may be electrically coupled to the lowermost patterned electrical conductor layer 22.

Another device aspect is directed to a multi-chip module 20′ that includes an interconnect layer stack 21′. The interconnect layer stack 21′ includes a plurality of patterned electrical conductor layers 22′, 25′, 27′ and a dielectric layer 23′, 26′ between adjacent patterned electrical conductor layers. The interconnect layer stack 21′ may have a thickness less than 50 microns, for example. The multi-chip module 20′ further includes a pair of IC die 31a′, 31b′ in a flip chip arrangement electrically coupled to an uppermost patterned electrical conductor layer 27′, and a first underfill dielectric layer 33′ between the pair of IC die and adjacent portions of the uppermost patterned electrical conductor layer. The multi-chip module 20′ further includes a plurality of solder contacts 37′ coupled to a lowermost patterned electrical conductor layer 22′.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A method of making a multi-chip module comprising:
forming an interconnect layer stack on a sacrificial substrate comprising a plurality of patterned electrical conductor layers, and a dielectric layer between adjacent patterned electrical conductor layers;
electrically coupling a first integrated circuit (IC) die in a flip chip arrangement to an uppermost patterned electrical conductor layer;
forming a first underfill layer between the first IC die and adjacent portions of the interconnect layer stack;
removing the sacrificial substrate to expose a lowermost patterned electrical conductor layer;
electrically coupling a second integrated circuit die in a flip chip arrangement to the lowermost patterned electrical conductor layer; and
forming a second underfill layer between the second IC die and adjacent portions of the interconnect layer stack.

2. The method according to claim 1, wherein the sacrificial substrate comprises glass.

3. The method according to claim 1, wherein the dielectric layer comprises polyimide.

4. The method according to claim 1, wherein the first and second underfill layers each comprises an epoxy material.

5. The method according to claim 1, wherein forming the interconnect layer stack comprises forming same to have a thickness less than 50 microns.

6. The method according to claim 1, wherein removing the sacrificial substrate comprises removing the sacrificial substrate by etching.

7. A method of making a multi-chip module comprising:
forming an interconnect layer stack on a sacrificial substrate comprising a plurality of patterned electrical conductor layers and a dielectric layer between adjacent patterned electrical conductor layers;
electrically coupling a first integrated circuit die in a flip chip arrangement to an uppermost patterned electrical conductor layer;
removing the sacrificial substrate to expose a lowermost patterned electrical conductor layer; and
forming a plurality of solder contacts on the lowermost patterned electrical conductor layer.

8. The method according to claim 7, wherein forming the plurality of solder contacts comprises forming a ball-grid array.

9. The method according to claim 7, wherein the sacrificial substrate comprises glass.

10. The method according to claim 7, wherein the dielectric layer comprises polyimide.

11. The method according to claim 7, further comprising forming a first underfill layer between the first IC die and adjacent portions of the interconnect layer stack; and wherein the first underfill layer comprises an epoxy material.

12. The method according to claim 9, wherein forming the interconnect layer stack comprises forming same to have a thickness less than 50 microns.

13. The method according to claim 9, wherein removing the sacrificial substrate comprises removing the sacrificial substrate by etching.

14. A multi-chip module comprising:
an interconnect layer stack comprising a plurality of patterned electrical conductor layers and a dielectric layer between adjacent patterned electrical conductor layers;
a first integrated circuit (IC) die in a flip chip arrangement electrically coupled to an uppermost patterned electrical conductor layer;
a first underfill layer between said first IC die and adjacent portions of said interconnect layer stack;
a second integrated circuit die in a flip chip arrangement electrically coupled to a lowermost patterned electrical conductor layer; and
a second underfill layer between said second IC die and adjacent portions of said interconnect layer stack.

15. The multi-chip module according to claim 14, wherein the first and second underfill layers each comprises an epoxy material.

16. The multi-chip module according to claim 14, wherein said interconnect layer stack has a thickness less than 50 microns.

17. A module comprising:
an interconnect layer stack comprising a plurality of patterned electrical conductor layers and a dielectric layer between adjacent patterned electrical conductor layers, the interconnect layer stack having a thickness less than 50 microns;
an integrated circuit (IC) die in a flip chip arrangement electrically coupled to an uppermost patterned electrical conductor layer;
a first underfill layer between said IC die and adjacent portions of said interconnect layer stack; and
a plurality of solder contacts coupled to a lowermost patterned electrical conductor interconnect layer.

18. The module according to claim 17, wherein said plurality of solder contacts comprises a ball-grid array.

19. The module according to claim 17, wherein the first underfill layer comprises an epoxy material.

20. The module according to claim 17, wherein said interconnect layer stack has a thickness greater than 5 microns.
